(19) United States
(12) Patent Application Publication
(10) Pub. No.: US 2025/0329369 A1
(43) Pub. Date: Oct. 23, 2025

(54) Gated Extend Re-Gate Synchronization Circuitry

(71) Applicant: Micron Technology, Inc., Boise, ID (US)

(72) Inventors: Brian W. Huber, Allen, TX (US); Mahmoud Jaffal, Plano, TX (US)

(21) Appl. No.: 18/974,555

(22) Filed: Dec. 9, 2024

Related U.S. Application Data
(60) Provisional application No. 63/637,733, filed on Apr. 23, 2024.

(51) Int. Cl. G11C 11/4076; G11C 11/4093; G11C 11/4096

(52) U.S. Cl. CPC G11C 11/4076; G11C 11/4093; G11C 11/4096

(57) ABSTRACT

A memory device includes a command interface configured to receive a write command from a host device. The memory device also includes an input/output interface configured to receive a data strobe. Furthermore, the memory device includes capture circuitry configured to capture the data strobe and generate an internal data strobe. The capture circuitry includes gated extend circuitry configured to extend an overlap of the data strobe with a start-to-synchronize signal that indicates that the data strobe is to be used in the memory device. Moreover, the capture circuitry includes re-gating circuitry configured to re-gate an output of the gated extend circuitry based at least in part on the start-to-synchronize signal.

### CROSS-REFERENCE TO RELATED APPLICATIONS

This application claims priority to U.S. Provisional Application No. 63/637,733, filed Apr. 23, 2024, which is incorporated by reference herein in its entirety.

### BACKGROUND

### Field of the Present Disclosure

Embodiments of the present disclosure relate generally to memory devices. More specifically, embodiments of the present disclosure relate to extending a state that is at least based in part on a strobe.

### Description of Related Art

Generally, a computing system may include electronic devices that, in operation, communicate information via electrical signals. These systems generally rely on states indicated by one or more signals often using strobe signals and/or clock signals to capture these states. For instance, a host device (e.g., processor) may send data and commands to memory devices. The memory devices utilize capture circuitry to capture input signals received from the host device to hold a state where the input signals can be used. For instance, the capture circuitry may include latches or flip-flips to perform such functions. However, these latches or flip-flops may add significant delay with feedback pathing and/or multiplexing. Additionally, these latches or flip-flops may need to be reset that may increase complexity in implementing and/or controlling the capture circuitry. Furthermore, the latches or flip-flops may have issues shutting off a strobe fast enough in some situations. For instance, when a relatively short preamble (0.5 tCK) is used, the memory device may shut off a data strobe (DQS) later than intended/specified.

Embodiments of the present disclosure may be directed to one or more of the problems set forth above.

### BRIEF DESCRIPTION OF THE DRAWINGS

FIG. 1 is a simplified block diagram illustrating certain features of a memory device having capture circuitry, according to an embodiment of the present disclosure;

FIG. 2 is a diagram of an embodiment of gated extend re-gate synchronization (GERS) circuitry of the capture circuitry of FIG. 1 with the GERS circuitry having fine-grain pulse extension circuitry, according to an embodiment of the present disclosure;

FIG. 3 is a diagram of an embodiment of complementary GERS circuitry of the capture circuitry of FIG. 1 with the complementary GERS circuitry having fine-grain pulse extension circuitry, according to an embodiment of the present disclosure;

FIG. 4 is a diagram of the fine-grain pulse extension circuitries of FIGS. 2 and 3, according to an embodiment of the present disclosure;

FIG. 5 is a diagram of the fine-grain pulse extension circuitries of FIGS. 2 and 3 with a bypass mode, according to an embodiment of the present disclosure;

FIG. 6 is a diagram of compounded GERS circuitry that includes the GERS circuitry of FIG. 2 and the complementary GERS circuitry of FIG. 3, according to an embodiment of the present disclosure;

FIG. 7 is a diagram of data strobe generation circuitry of the memory device that includes the compounded GERS circuitry of FIG. 6, according to an embodiment of the present disclosure;

FIG. 8 is a timing diagram using the data strobe generation circuitry of FIG. 7 for enabling the data strobe during a write operation, according to an embodiment of the present disclosure;

FIG. 9 is a timing diagram using the data strobe generation circuitry of FIG. 7 for disabling the data strobe after a write operation, according to an embodiment of the present disclosure;

FIG. 10 is a timing diagram using the data strobe generation circuitry of FIG. 7 for enabling the data strobe false during a write operation, according to an embodiment of the present disclosure;

FIG. 11 is a timing diagram using the data strobe generation circuitry of FIG. 7 for disabling the data strobe false after a write operation, according to an embodiment of the present disclosure;

FIG. 12 is a timing diagram using the data strobe generation circuitry of FIG. 7 for enabling the data strobe during a write operation for slower frequency operations, according to an embodiment of the present disclosure;

FIG. 13 is a timing diagram using the data strobe generation circuitry of FIG. 7 for disabling the data strobe after a write operation for slower frequency operations, according to an embodiment of the present disclosure;

FIG. 14 is a timing diagram using the data strobe generation circuitry of FIG. 7 for enabling the data strobe false during a write operation for slower frequency operations, according to an embodiment of the present disclosure;

FIG. 15 is a timing diagram using the data strobe generation circuitry of FIG. 7 for disabling the data strobe false after a write operation for slower frequency operations, according to an embodiment of the present disclosure; and

FIG. 16 is a diagram of a NOR gate of the complementary GERS circuitry of FIG. 3 and a NAND gate of the GERS circuitry of FIG. 2, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As discussed below, gated extend re-gate synchronization (GERS) circuitry may be used to hold states when input states overlap. For instance, a strobe (e.g., DQS) may be used in an electronic device (e.g., memory device). However, this strobe may not run continuously. Thus, a signal-to-synchronize (STS) may be used to enable the strobe to traverse the capture circuitry. The GERS circuitry may have similar characteristics to a strobed latch but as a feed-forward flow rather than with a feedback node avoiding feedback-related delays and avoiding any uncertainties related to a tri-state feedback node. As discussed below, the state of the GERS may have a limited lifetime/duration related to pulse extension rather than relying on explicit resets or feedback in a typical strobed latch. Further, the delay through the GERS may be relatively less than a strobed latch. The GERS may also be more sensitive to successfully register a late STS just prior to the strobe going inactive or where the strobe has a reduced active time/poor duty cycle.

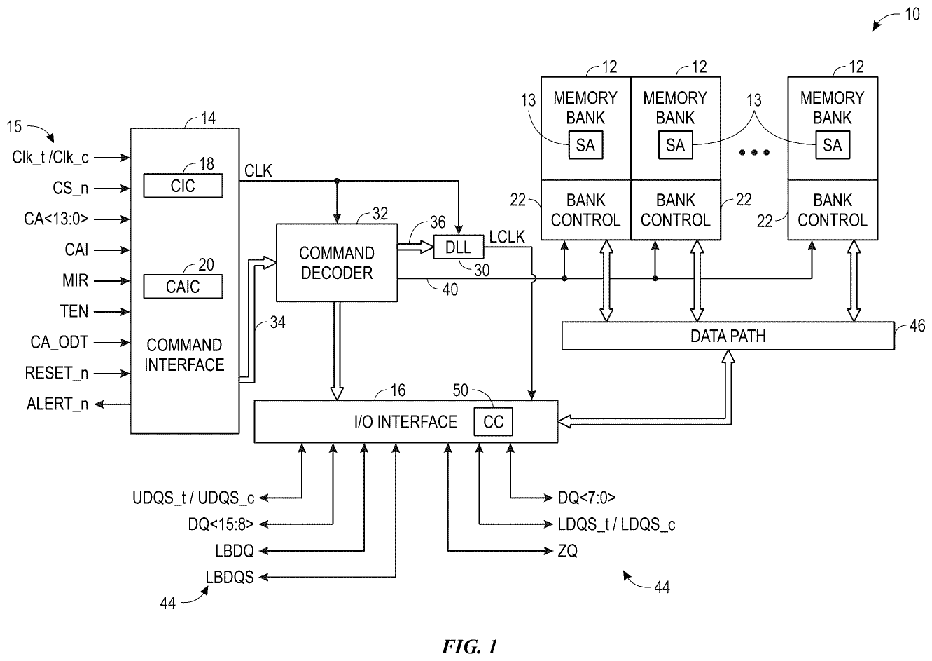

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random-access memory (DDR5 SDRAM) device. Various features of DDR5 SDRAM allow for reduced power consumption, more bandwidth and more storage capacity compared to prior generations of DDR SDRAM.

The memory device 10 may include a number of memory banks 12. The memory banks 12 may be DDR5 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR5, the memory banks 12 may be further arranged to form bank groups. For instance, for an 8 gigabyte (Gb) DDR5 SDRAM, the memory chip may include 16 memory banks 12, arranged into 8 bank groups, each bank group including 2 memory banks. For a 16 Gb DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application and design of the overall system.

The memory banks 12 and/or bank control blocks 22 include sense amplifiers 13. As previously noted, sense amplifiers 13 are used by the memory device 10 during read operations. Specifically, read circuitry of the memory device 10 utilizes the sense amplifiers 13 to receive low voltage (e.g., low differential) signals from the memory cells of the memory banks 12 and amplifies the small voltage differences to enable the memory device 10 to interpret the data properly.

The memory device 10 may include a command interface 14 and an input/output (I/O) interface 16. The command interface 14 is configured to provide a number of signals (e.g., signals 15) from an external (e.g., host) device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, the true clock signal Clk_t and the bar clock signal Clk_c. The positive clock edge for DDR refers to the point where the rising true clock signal Clk_t crosses the falling bar clock signal Clk_c, while the negative clock edge indicates that transition of the falling true clock signal Clk_t and the rising of the bar clock signal Clk_c. Commands (e.g., read command, write command, etc.) are typically entered on the positive edges of the clock signal and data is transmitted or received on both the positive and negative clock edges.

The clock input circuit 18 receives the true clock signal Clk_t and the bar clock signal Clk_c and generates an internal clock signal CLK. The internal clock signal CLK is supplied to an internal clock generator, such as a delay locked loop (DLL) circuit 30. The DLL circuit 30 generates a phase controlled internal clock signal LCLK based on the received internal clock signal CLK. The phase controlled internal clock signal LCLK is supplied to the I/O interface 16, for instance, and is used as a timing signal for determining an output timing of read data. In some embodiments, the clock input circuit 18 may include circuitry that splits the clock signal into multiple (e.g., 4) phases. The clock input circuit 18 may also include phase detection circuitry to detect which phase receives a first pulse when sets of pulses occur too frequently to enable the clock input circuit 18 to reset between sets of pulses.

The internal clock signal(s)/phases CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the DLL circuit 30 over the bus 36 to coordinate generation of the phase controlled internal clock signal LCLK. The phase controlled internal clock signal LCLK may be used to clock data through the IO interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes the bank control block 22 which provides the necessary decoding (e.g., row decoder and column decoder), as well as other features, such as timing control and data control, to facilitate the execution of commands to and from the memory banks 12.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20, which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the IO interface 16. More specifically, the data may be sent to or retrieved from the memory banks 12 over the data path 46, which includes a plurality of bi-directional data buses. Data IO signals, generally referred to as DQ signals, are generally transmitted and received in one or more bi-directional data busses. For certain memory devices, such as a DDR5 SDRAM memory device, the IO signals may be divided into upper and lower bytes. For instance, for a x16 memory device, the IO signals may be divided into upper and lower IO signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance. As previously discussed, the memory device 10 may include capture circuitry 50 that is used to gate and/or capture a signal (e.g., DQS signals) and propagate it based on another signal (e.g., STS, write enable, etc.). Although the capture circuitry 50 is illustrated in the I/O interface 16, it may be additionally or alternatively located in any location within the memory device 10 where such signal capture and/or gating may occur. Indeed, such capture and gate functionality may be used in other electronic devices that are not memory devices. Therefore, such electronic devices may utilize the capture circuitry 50. In other words, the discussion below in relation to the capture circuitry may be deployed in non-memory devices. Furthermore, as discussed below, the capture circuitry may be used on complementary signals and may include true and complementary circuitry.

An impedance (ZQ) calibration signal may also be provided to the memory device 10 through the IO interface 16. The ZQ calibration signal may be provided to a reference pin and used to tune output drivers and ODT values by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback data signal (LBDQ) and loopback strobe signal (LBDQS) may be provided to the memory device 10 through the IO interface 16. The loopback data signal and the loopback strobe signal may be used during a test or debugging phase to set the memory device 10 into a mode wherein signals are looped back through the memory device 10 through the same pin. For instance, the loopback signal may be used to set the memory device 10 to test the data output (DQ) of the memory device 10. Loopback may include both LBDQ and LBDQS or possibly just a loopback data pin. This is generally intended to be used to monitor the data captured by the memory device 10 at the IO interface 16. LBDQ may be indicative of a target memory device, such as memory device 10, data operation and, thus, may be analyzed to monitor (e.g., debug and/or perform diagnostics on) data operation of the target memory device. Additionally, LBDQS may be indicative of a target memory device, such as memory device 10, strobe operation (e.g., clocking of data operation) and, thus, may be analyzed to monitor (e.g., debug and/or perform diagnostics on) strobe operation of the target memory device.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description. Furthermore, although the foregoing discusses the memory device 10 as being a DDR5 device, the memory device 10 may be any suitable device (e.g., a double data rate type 4 DRAM (DDR4), a ferroelectric RAM device, or a combination of different types of memory devices).

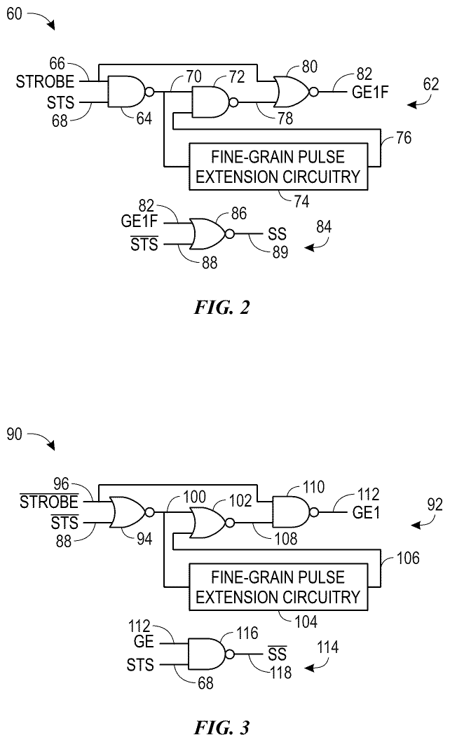

FIG. 2 is a diagram of gated extend re-gate synchronization (GERS) circuitry 60 that may be included in the capture circuitry 50. As illustrated, the GERS circuitry 60 includes gated extend circuitry 62 that extends a state occurring at inputs of the GERS circuitry 60. As illustrated, the GERS circuitry 60 includes a NAND gate 64 that receives a strobe 66 and a start-to-synchronize (STS) signal 68. As previously noted, the strobe 66 may be any strobe or clock (e.g., DQS) that may be used in an electronic device. For example, in the memory device 10, the strobe 66 may be derived from and/or be a DQS_t signal. As previously noted, the STS 68 may be any signal indicating that the strobe/clock is to be synchronized. For example, the STS 68 may be derived from a write command and/or may include signals indicating start and/or end of a write operation occurring (e.g., WrStart and/or WrEnd, etc.). An output 70 of the NAND gate 64 is transmitted to a NAND gate 72 and fine-grain pulse extension circuitry 74 that extends a pulse of the output 70. An extended pulse output 76 is output from the fine-grain pulse extension circuitry 74 as another input to the NAND gate 72. An output 78 of the NAND gate 72 is used as an input to a NOR gate 80 with the strobe 66 being another input to the NOR gate 80. An output of the NOR gate 80 is a gated extend false (GE1F) 82. The GE1F 82 is transmitted to re-gating circuitry 84 that also receives STS bar 88 that is complementary to the STS 68. The STS bar 88 and the GE1F 82 are used as inputs of a NOR gate 86 of the re-gating circuitry 84 while an output of the NOR gate 86 is a synchronized signal (SS) 89 that is the extended and synchronized state based on strobes of the strobe 66 and the STS 68 overlapping.

As previously noted, the capture circuitry 50 may be used for differential/complementary signals. Accordingly, the capture circuitry 50 may include complementary GERS circuitry, such as complementary GERS circuitry 90 in FIG. 3. The complementary GERS circuitry 90 includes gated extend circuitry 92. The gated extend circuitry 92 includes a NOR gate 94 that receives a strobe bar 96 and the STS bar 88. An output 100 of the NOR gate 94 is transmitted to a NOR gate 102 and fine-grain pulse extension circuitry 104 that extends a pulse of the output 100. As discussed below, the fine-grain pulse extension circuitry 104 may be similar to and/or with a complementary configuration to the fine-grain pulse extension circuitry 74 of FIG. 2. An extended pulse output 106 is output from the fine-grain pulse extension circuitry 104 as another input to the NOR gate 102. An output 108 of the NOR gate 102 is used as an input to a NAND gate 110 with the strobe bar 96 being another input to the NAND gate 110. An output of the NAND gate 110 is a gated extend (GE1) 112. The GE1 112 is transmitted to re-gating circuitry 114 that also receives the STS 68. The STS 68 and the GE1 112 are used as inputs of a NAND gate 116 of the re-gating circuitry 114 while an output of the NAND gate 116 is an SS bar 118 that is the extended and synchronized state-based pulses on the strobe bar 96 and the STS bar 88 overlapping.

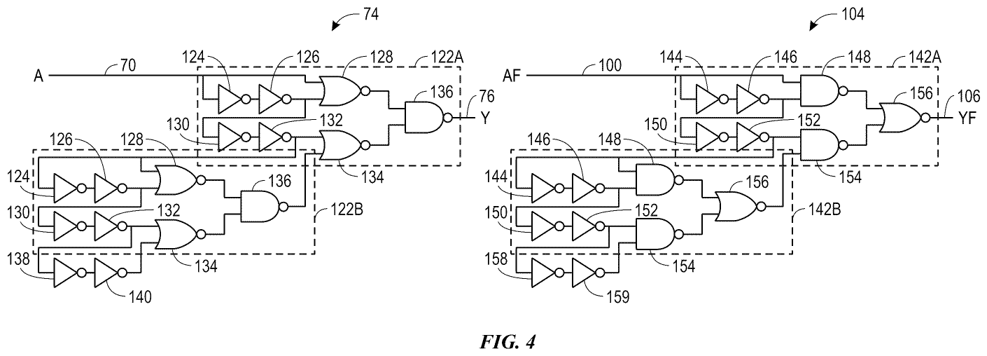

FIG. 4 shows an example embodiment of the fine-grain pulse extension circuitry 74 and the complementary logic in the fine-grain pulse extension circuitry 104. Although the illustrated embodiments of the fine-grain pulse extension circuitry 74 and the fine-grain pulse extension circuitry 104 are illustrated with a specific embodiment, other equivalent logic solutions may be used. For instance, the illustrated embodiments of the fine-grain pulse extension circuitry 74 and the complementary logic in the fine-grain pulse extension circuitry 104 are illustrated with explicit inverters while other embodiments may be more weighted towards NAND and NOR gates. However, the inverter-weighted embodiments provide a finer grain capability to provide a better reproduction signal quality for narrower pulses. As illustrated, the fine-grain pulse extension circuitry 74 and the complementary logic in the fine-grain pulse extension circuitry 104 includes expansion circuitries 122 (individually 122A and 122B) and 142 (142A and 142B) that may be added or subtracted to change the amount of extension in the fine-grain pulse extension circuitry 74 and the complementary logic in the fine-grain pulse extension circuitry 104.

The expansion circuitries 122 receive an input (e.g., the output 70) and transmit it to serial inverters 124 and 126 to invert the input back to its original logic but on a delay with the original and delayed input to a NOR gate 128. The delayed input/output of the serial inverters 130 and 132 is then used as an input to additional serial inverters 130 and 132 to further delay the input. An output of these additional serial inverters 130 and 132 are transmitted to a NOR gate 134. The output of these additional serial inverters 130 and 132 may be used as an input to another expansion circuitry (e.g., the expansion circuitry 122B). In a lowest-order expansion circuitry (e.g., the expansion circuitry 122B), this output of the additional serial inverters 130 and 132 may be input to serial inverters 138 and 140 whose output is then fed back into its NOR gate 134. The output of each NOR gate 134 along with an output of the NOR gate 128 is transmitted as an input to a NAND gate 136. If there is a higher order expansion circuitry 122 closer to an input to the fine-grain pulse extension circuitry 74 (e.g., expansion circuitry 122A) than a lower-order expansion circuitry 122 (e.g., expansion circuitry 122B) further from the input, the output of the NAND gate 136 of the lower order expansion circuitry 122 is transmitted as an input of the NOR gate 134 of the higher order expansion circuitry 122. From the highest order expansion circuitry 122, the output of the NAND gate 136 is the extended pulse output 76 that has an extension of the pulse occurring from an overlap of the strobe 66 and the STS 68.

The expansion circuitries 142 receive an input (e.g., the output 100) and transmit it to serial inverters 144 and 146 to invert the input back to its original logic but on a delay with the original and delayed input to a NAND gate 148. The delayed input/output of the serial inverters 150 and 152 is then used as an input to additional serial inverters 150 and 152 to further delay the input. An output of these additional serial inverters 150 and 152 are transmitted to a NAND gate 154. The output of these additional serial inverters 150 and 152 may be used as an input to another expansion circuitry (e.g., the expansion circuitry 142B). In a lowest-order expansion circuitry (e.g., the expansion circuitry 142B), this output of the additional serial inverters 150 and 152 may be input to serial inverters 158 and 159 whose output is then fed back into its NAND gate 154. The output of each NAND gate 154 along with an output of the NAND gate 148 is transmitted as an input to a NOR gate 156. If there is a higher order expansion circuitry 142 closer to an input to the fine-grain pulse extension circuitry 104 (e.g., expansion circuitry 142A) than a lower-order expansion circuitry 142 (e.g., expansion circuitry 142B) further from the input, the output of the NOR gate 156 of the lower order expansion circuitry 142 is transmitted as an input of the NAND gate 154 of the higher order expansion circuitry 142. From the highest order expansion circuitry 142, the output of the NOR gate 156 is the extended pulse output 106 that has an extension of the pulse occurring from an overlap of the strobe bar 96 and the STS bar 88. Thus, the extended pulse output 106 is complementary to the extended pulse output 76.

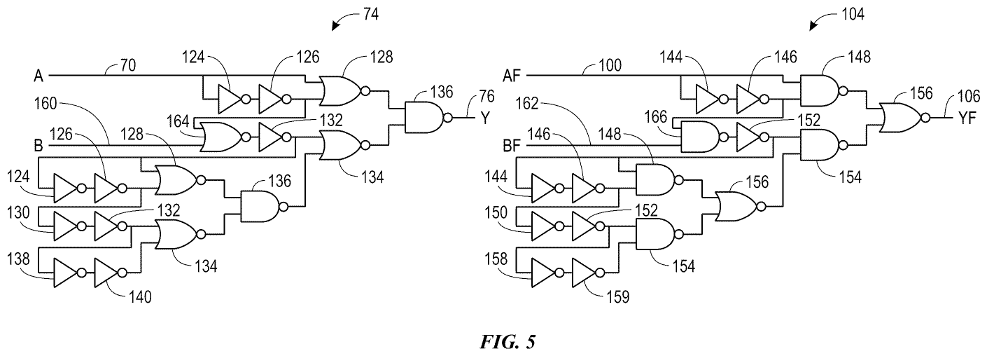

In some situations, the fine-grain pulse extension circuitry 74 and the fine-grain pulse extension circuitry 104 may use a special mode that forces a state. One benefit of placing such circuitry in this less critical path may enable such insertion without introducing latency or signal quality issues via the other critical paths. FIG. 5 shows alternative embodiments of the fine-grain pulse extension circuitry 74 and the fine-grain pulse extension circuitry 104 that uses a B signal 160 or a complementary BF signal 162 to force the fine-grain pulse extension circuitry 74 and the fine-grain pulse extension circuitry 104 to have their outputs forces to an active state. As illustrated, in the fine-grain pulse extension circuitry 74 of FIG. 5, the B signal 160 is transmitted to a NOR gate 164 that replaces the inverter 130 of the fine-grained pulse extension circuitry 74. Similarly, in the fine-grain pulse extension circuitry 104 of FIG. 5, the BF signal 162 is transmitted to a NAND gate 166 that replaces the inverter 150 of the fine-grained pulse extension circuitry 104.

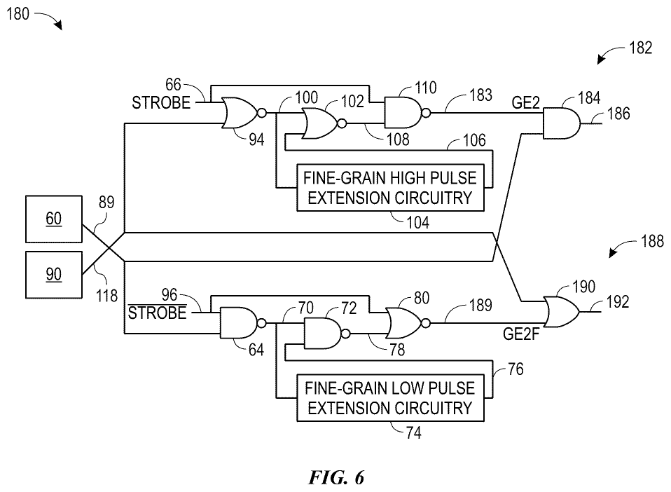

When timing is critical, dual-ended signal and logic are typically employed. The GERS circuitry 60 and the complementary GERS circuitry 90 may be compounded together serially in a cross-coupled fashion as shown in compounded GERS circuitry 180 of FIG. 6. As illustrated, the compounded GERS circuitry 180 includes the GERS circuitry 60 and the complementary GERS circuitry 90.

The complementary GERS circuitry 90 transmits it output, SS bar 118, to complementary GERS circuitry 182 that is similar to the complementary GERS circuitry 90 except that the STS bar 88 is replaced by the SS bar 118 as an input to the NOR gate 94. Additionally, in the complementary GERS circuitry 182, the NAND gate 116 is replaced by an AND gate 184 that receives GE2F 183 along with the SS 89 from the GERS circuitry 60. The AND gate 184 may be used instead of a corresponding NAND gate 116 for logic purposes. For instance, the inverting logic of the NAND operation may be collapsed into a next stage. The output of the AND gate 184 is a synchronized compounded signal (SCS) 186 is generated using strobe negative edge triggering.

The GERS circuitry 60 transmits it output, SS 89, to GERS circuitry 188 that is similar to the GERS circuitry 60 except that the STS 68 is replaced by the SS 89 as an input to the NAND gate 64. Additionally, in the GERS circuitry 188, the NOR gate 86 is replaced by an OR gate 190 that receives GE2 189 along with the SS bar 118 from the complementary GERS circuitry 90. Like the AND gate 184, the OR gate 190 may be used instead of a corresponding NOR gate 86 for logic purposes. For instance, the inverting logic of the NOR operation may be collapsed into a next stage. The output of the OR gate 190 is an SCS bar 192 that is generated using strobe negative edge triggering and is complementary to the SCS 186.

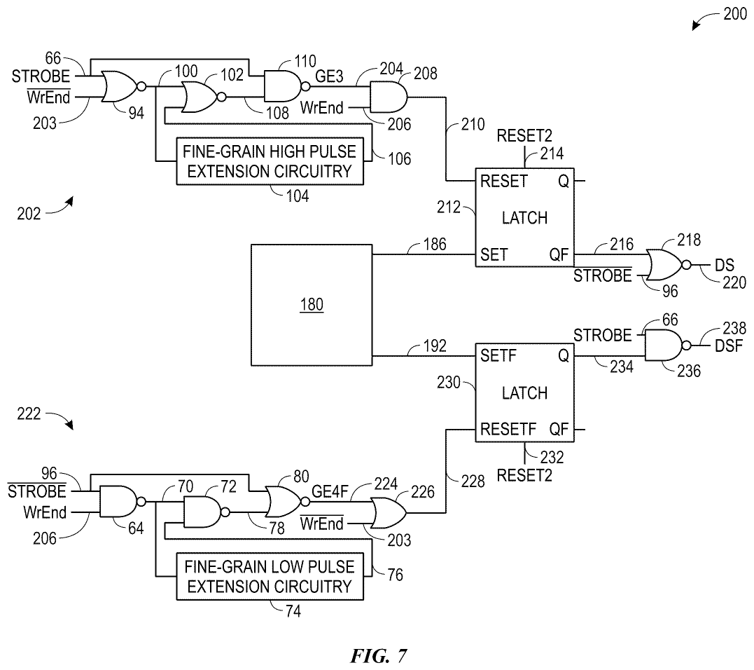

As previously noted, the capture circuitry 50 may be used in a memory device, such as the memory device 10. FIG. 7 is a diagram of an embodiment of data strobe (DS) generation circuitry 200 that includes the compounded GERS circuitry 180. In such an embodiment, the STS 68 may be and/or be based on a write command (e.g., WrStart signal) indicating that a write is to start. In the illustrated embodiment, the DS generation circuitry 200 also includes reset circuitry 202 and 222 that are respectively similar to the complementary GERS circuitry 182 and the GERS circuitry 188. The reset circuitry 202 is like the complementary GERS circuitry 182 except that the reset circuitry 202 uses a write end false (WrEnd bar) 203 as the STS bar 88 since the reset is to occur after a write operation ends. The output of the NAND gate 111 of the reset circuitry 202 extends a state based on the strobe 66 and the WrEnd bar 203. Thus, the output of the NAND gate 111 is a gated extend (GE3) 204. An AND gate 208 is used to re-gate the GE3 204 with WrEnd 206 that is complementary to the WrEnd bar 203. An output 210 of the AND gate 208 is used to reset a latch 212 that is set using the SCS 186. The latch 212 may also be able to receive an alternative reset signal 214 that may use a non-critical reset path used for initialization and/or other special modes.

As previously noted, the reset circuitry 222 is like the GERS circuitry 188 except that the reset circuitry 202 uses WrEnd bar 203 as the STS 68 since the reset is to occur after a write operation ends. The output of the NOR gate 80 of the reset circuitry 222 extends a state based on the strobe bar 96 and the WrEnd 206. Thus, the output of the NOR gate 80 is a gated extend false (GE3F) 224 that is complementary to GE3 204. An OR gate 226 is used to re-gate the GE4F 224 with WrEnd bar 203. An output 228 of the OR gate 226 is used to reset a latch 230 that is set using the SCS bar 192. The latch 230 may also be able to receive an alternative reset signal 232 that may use a non-critical reset path used for initialization and/or other special modes.

Respective outputs 216 and 234 of the latches 212 and 230 are used to generate DS signaling. Specifically, the output 216 is transmitted to a NOR gate 218 along with the strobe bar 96 to generate DS 220 used to capture data at pads (e.g., DQ pads) for memory operations (e.g., write operations). Likewise, the output 234 is transmitted to a NAND gate 236 along with the strobe 66 to generate a data strobe false (DSF) 238 used to assist in capturing data for the memory operations.

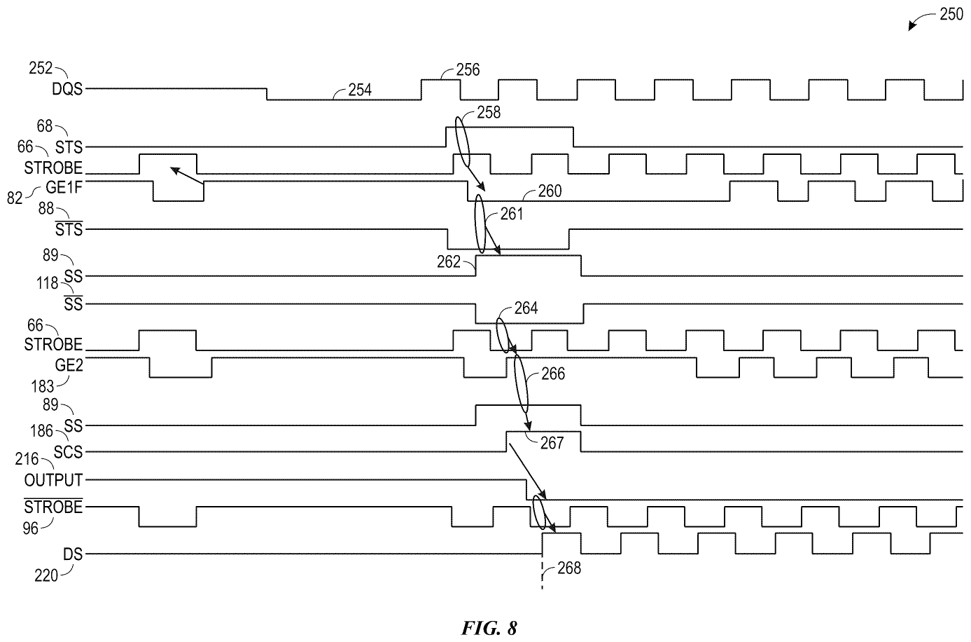

FIG. 8 is a timing diagram 250 of enablement of the DS 220. The timing diagram 250 includes DQS 252 (e.g., UDQS_t or LDQS_t) that may be received at a pad of the memory device. As illustrated, the DQS 252 includes a write preamble low 254 followed by a write preamble high 256. Before the write preamble low 254, DQS 252 is either in a high impedance state or driven for another die rather than the present die. As previously noted, the strobe 66 is based on the DQS 252, but the strobe 66 may be glitchy before the preamble. After the preamble and at point 258, the STS 68 and the strobe 66 have overlapping pulses that lead to an extended state 260 on the GE1F 82. STS bar 88 then is used to re-gate 261 GE1F 82 to cause an extended and synchronized state or overlap 264 on the SS 89. Likewise, an overlap 264 of pulses of the SS bar 118 and the strobe 66 is extended on the GE2 183. GE2 183 is then re-gated 266 with the SS 89 to provide a synchronized and extended state 267 on the SCS 186. The synchronized and extended state 267 on the SCS 186 causes the latch 212 to toggle its output 216 to enable the strobe bar 96 to run freely through the NOR gate 218 to enable the DS 220 after point 268.

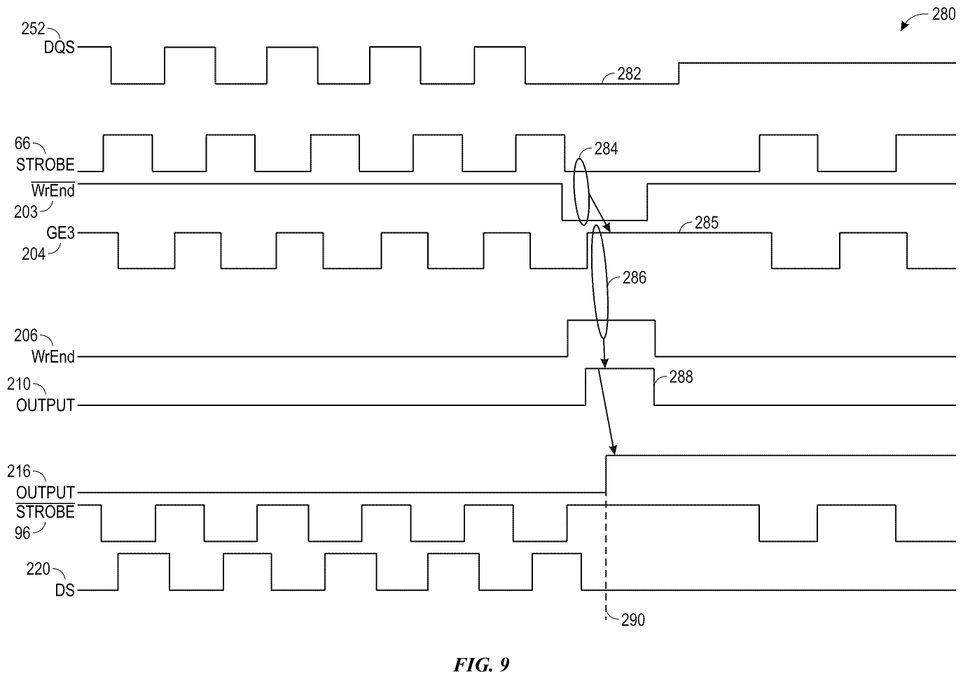

FIG. 9 is a timing diagram 280 of disablement of the DS 220. At the beginning of the timing diagram 280, DS 220 runs freely based on the DQS 252 before a write postamble 282. After the write postamble 282, the DQS 252 may go to a high impedance state or may be driven for other die. Since the DQS 252 may be in a high impedance state, the strobe 66 may be glitchy after the write postamble 282. When the WrEnd bar 203 pulses and overlaps 284 a pulse of the strobe 66, it causes an extended state 285 on the GE3 204. This extended state 285 is then re-gated 286 with the WrEnd 206 to create a pulse 288 on the output 210 that resets the latch 212 that causes it to de-assert the output 216 at time 290. The de-assertion of the output 216 causes the DS 220 to be cut off after time 290.

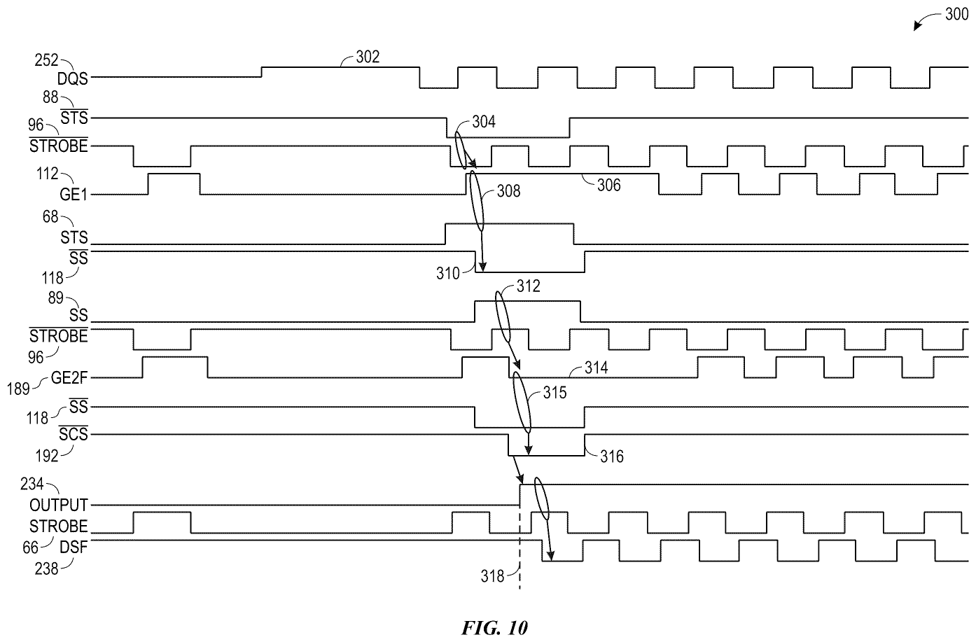

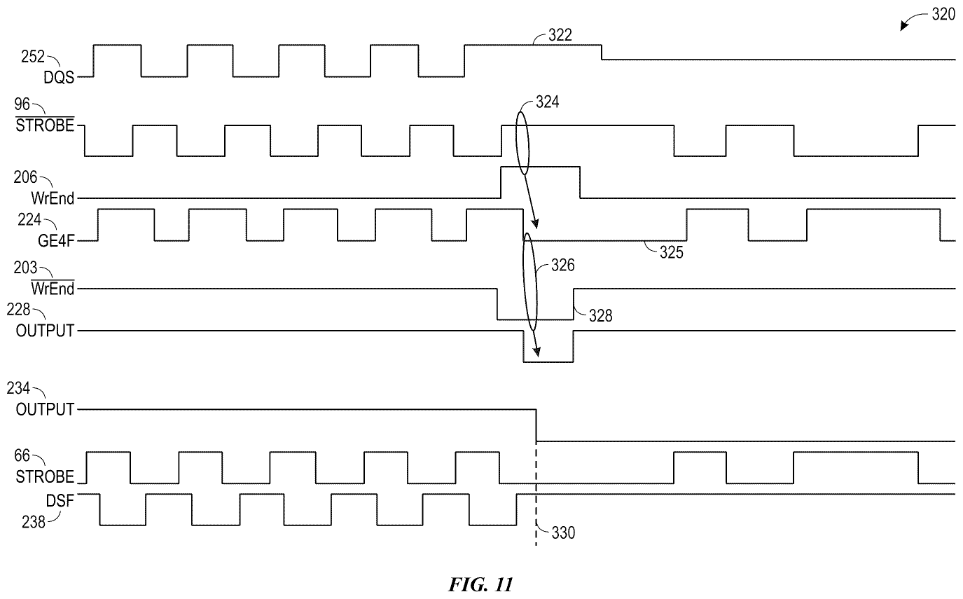

FIG. 10 is a timing diagram 300 of enablement of the DSF 238. The timing diagram 300 also includes DQS 252 (e.g., UDQS_t or LDQS_t) that may be received at a pad of the memory device. As illustrated, the DQS 252 includes a write preamble 302. Before the write preamble 302, DQS 252 is either in a high impedance state or driven for another die rather than the present die that may cause the strobe to be glitchy before the write preamble 302. After the write preamble 302, pulses of the STS bar 88 and the strobe 66 overlap 304 that lead to an extended state 306 on the GE1 112. STS 68 then is used to re-gate 308 GE1 112 to cause an extended and synchronized state 310 on the SS bar 118. Likewise, an overlap 312 of pulses of the SS 89 and the strobe bar 96 causes a pulse 314 on the GE2F 189. GE2F 189 is then re-gated 315 with the SS bar 118 to provide a synchronized and extended state 316 on the SCS bar 192. The synchronized and extended state 316 on the SCS bar 192 causes the latch 230 to toggle its output 234 at time 318 to enable the strobe 66 to run freely through the NAND gate 236 to enable the DSF 238 after time 318.

FIG. 11 is a timing diagram 320 of disablement of the DSF 238. At the beginning of the timing diagram 320, DSF 238 runs freely based on the DQS 252 before a write postamble 322. After the write postamble 322, the DQS 252 may go to a high impedance state or may be driven for other die. Since the DQS 252 may be in a high impedance state, the strobe 66 may be glitchy after the write postamble 322. When the WrEnd 206 pulses and overlaps 324 a pulse of the strobe 66, it causes an extended state 325 on GE4F 224. This extended state 325 is then re-gated 326 with the WrEnd bar 203 to create a pulse 328 on the output 228 that resets the latch 230 that causes it to de-assert the output 234 at time 330. The de-assertion of the output 234 causes the DSF 238 to be cut off after time 330.

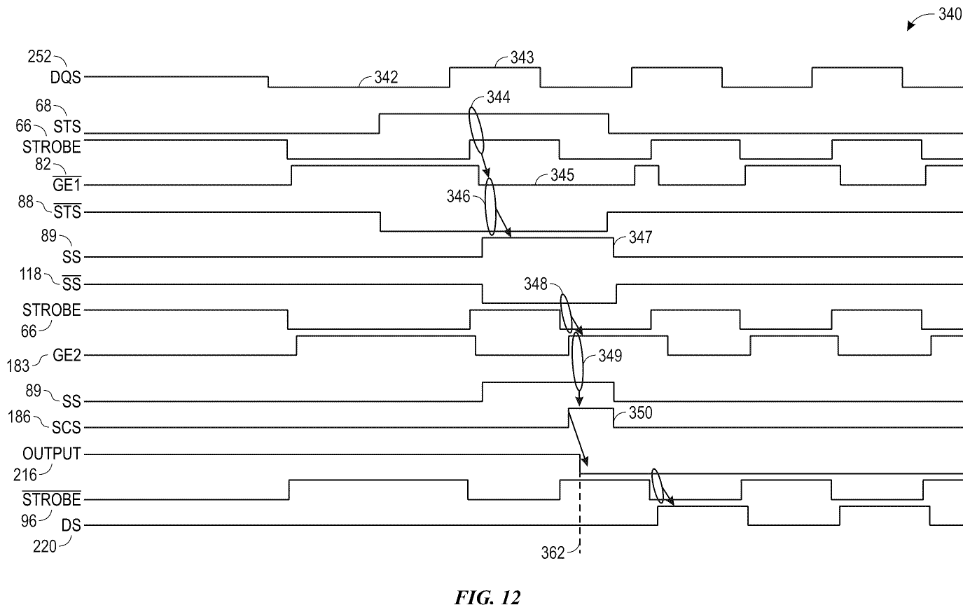

FIG. 12 is a timing diagram 340 of enablement of the DS 220 using lower frequency pathing. Like the timing diagram 250, the timing diagram 340 includes DQS 252 (e.g., UDQS_t or LDQS_t) that may be received at a pad of the memory device. As illustrated, the DQS 252 includes a write preamble low 342 followed by a write preamble high 343. Before the write preamble low 342, DQS 252 is either in a high impedance state or driven for another die that may cause the strobe 66 to be glitchy before the preamble. After the preamble, the STS 68 and the strobe 66 have pulses that overlap 344 that lead to an extended state 345 on the GE1F 82. STS bar 88 then is used to re-gate 346 GE1F 82 to cause an extended and synchronized state 347 on the SS 89. Likewise, an overlap 348 of pulses of the SS bar 118 and the strobe 66 is extended on the GE2 183. GE2 183 is then re-gated 349 with the SS 89 to provide a synchronized and extended state 350 on the SCS 186. The synchronized and extended state 350 on the SCS 186 causes the latch 212 to toggle its output 216 to enable the strobe bar 96 to run freely through the NOR gate 218 to enable the DS 220 after point 362.

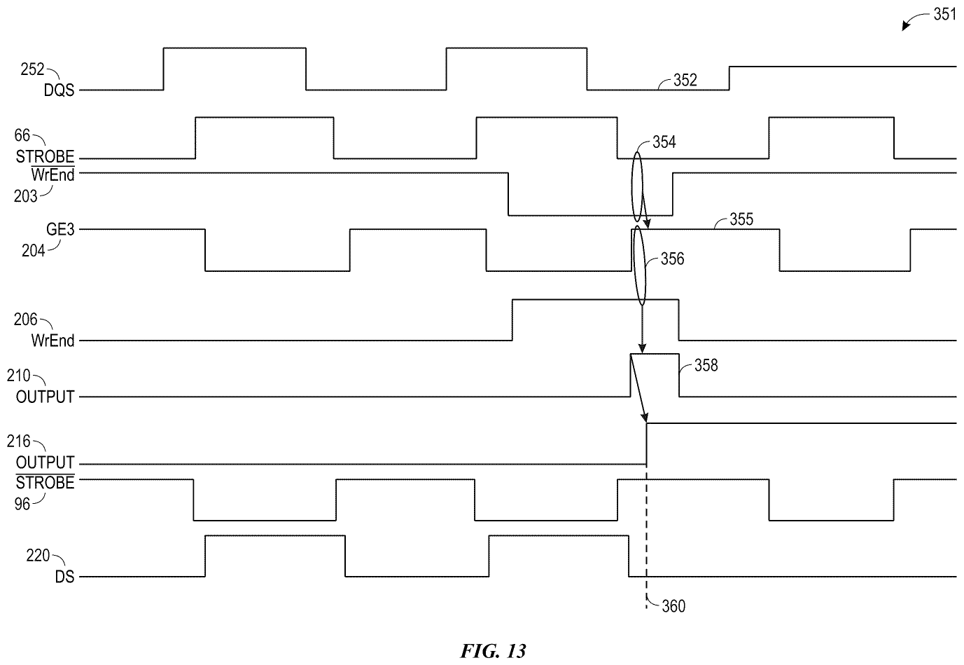

FIG. 13 is a timing diagram 351 of disablement of the DS 220 using lower frequency pathing. At the beginning of the timing diagram 351, DS 220 runs freely based on the DQS 252 before a write postamble 352. After the write postamble 352, the DQS 252 may go to a high impedance state or may be driven for other die. Since the DQS 252 may be in a high impedance state, the strobe 66 may be glitchy after the write postamble 352. When the WrEnd bar 203 pulses and overlaps 354 a pulse of the strobe 66, it causes an extended state 355 on the GE3 204. This extended state 355 is then re-gated 356 with the WrEnd 206 to create a pulse 358 on the output 210 that resets the latch 212 that causes it to de-assert the output 216 at time 360. The de-assertion of the output 216 causes the DS 220 to be cut off after time 360.

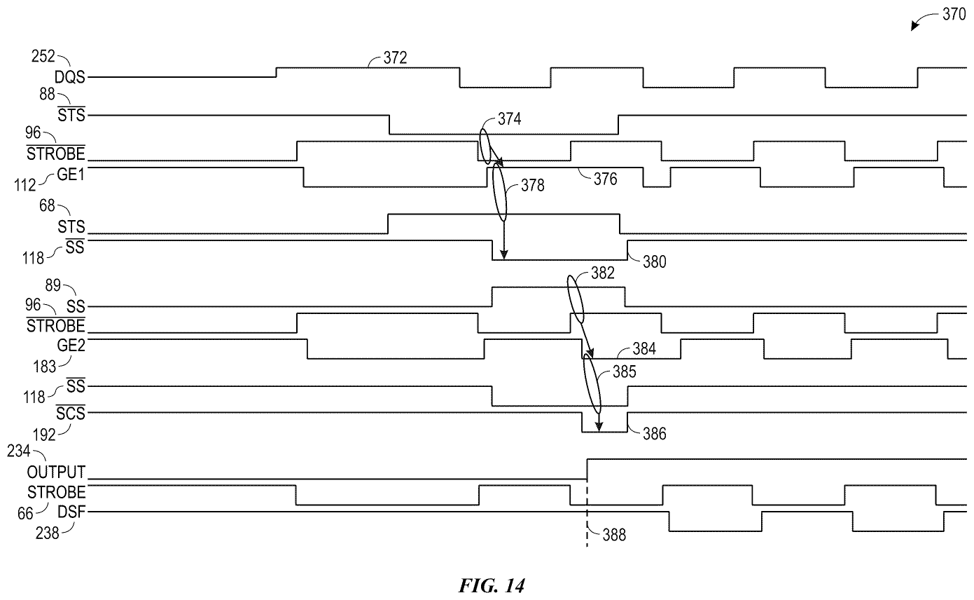

FIG. 14 is a timing diagram 370 of enablement of the DSF 238. The timing diagram 370 also includes DQS 252 (e.g., UDQS_t or LDQS_t) that may be received at a pad of the memory device. As illustrated, the DQS 252 includes a write preamble 372. Before the write preamble 372, DQS 252 is either in a high impedance state or driven for another die rather than the present die that may cause the strobe to be glitchy before the write preamble 372. After the write preamble 372, pulses of the STS bar 88 and the strobe 66 overlap 374 that lead to an extended state 376 on the GE1 112. STS 68 then is used to re-gate 378 GE1 112 to cause an extended and synchronized state 380 on the SS bar 118. Likewise, an overlap 382 of pulses of the SS 89 and the strobe bar 96 causes a pulse 384 on the GE2F 189. GE2F 189 is then re-gated 385 with the SS bar 118 to provide a synchronized and extended state 386 on the SCS bar 192. The synchronized and extended state 386 on the SCS bar 192 causes the latch 230 to toggle its output 234 at time 388 to enable the strobe 66 to run freely through the NAND gate 236 to enable the DSF 238 after time 388.

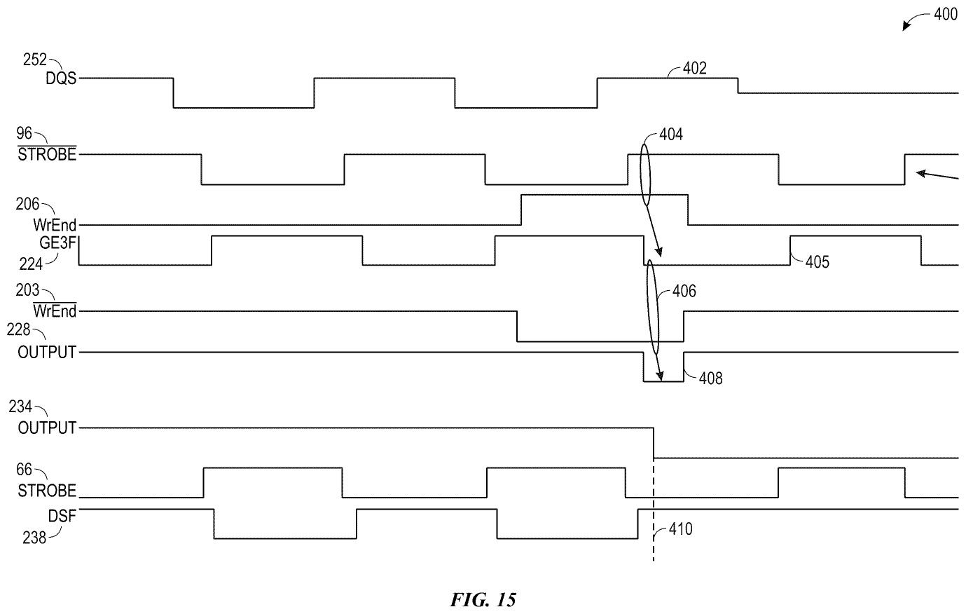

FIG. 15 is a timing diagram 400 of disablement of the DSF 238 using lower frequency pathing. At the beginning of the timing diagram 400, DSF 238 runs freely based on the DQS 252 before a write postamble 402. After the write postamble 402, the DQS 252 may go to a high impedance state or may be driven for other die. Since the DQS 252 may be in a high impedance state, the strobe 66 may be glitchy after the write postamble 402. When the WrEnd 206 pulses and overlaps 404 a pulse of the strobe 66, it causes an extended state 405 on GE4F 224. This extended state 405 is then re-gated 406 with the WrEnd bar 203 to create a pulse 408 on the output 228 that resets the latch 230 that causes it to de-assert the output 234 at time 410. The de-assertion of the output 234 causes the DSF 238 to be cut off after time 410.

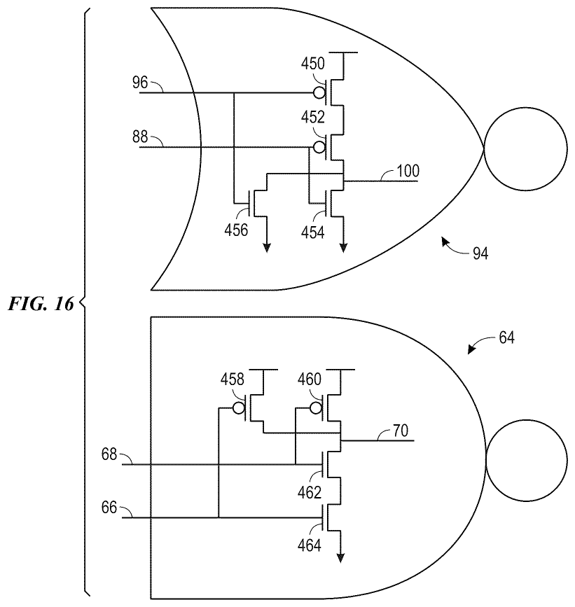

In some embodiments, the extension of the states may be at least partially performed and/or enhanced by skewing the strobe 66 and strobe bar 96 paths. This skewing ensures that STS 68 and STS bar 88-triggered extension is extended further by supplementing or replacing the fine-grain pulse extension circuitries 74 and 104. This skewing may be implemented by weakening at least one transistor in the GERS circuitry 60 and/or the complementary GERS circuitry 90. For instance, the NAND gate 64 of the GERS circuitry 60 may be weaker than other transistors in the GERS circuitry 60, and/or the NOR gate 94 of the complementary GERS circuitry 90 may be weaker than other transistors in the complementary GERS circuitry 90. FIG. 16 shows an embodiment of the NOR gate 94 and the NAND gate 64. The NOR gate 94 includes PMOS transistors 450 and 452 coupled in series and NMOS transistors 454 and 456. Weakening the NMOS transistor 456 relative to other transistors may extend the pulse extension further by skewing the strobe bar 96 related path. The NAND gate 64 includes PMOS transistors 458 and 460 along with NMOS transistors 462 and 464. Weakening the PMOS transistor 458 relative to other transistors may extend the pulse extension further by skewing the strobe 66 related path.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . .”, it is intended that such elements are to be interpreted under 35 U.S.C. 112(f). However, for any claims containing elements designated in any other manner, it is intended that such elements are not to be interpreted under 35 U.S.C. 112(f).

1. A memory device, comprising:
a command interface configured to receive a write command from a host device;
an input/output interface configured to receive a data strobe;
capture circuitry configured to capture the data strobe and generate an internal data strobe, wherein the capture circuitry comprises:
gated extend circuitry configured to extend an overlap of the data strobe with a start-to-synchronize signal that indicates that the data strobe is to be used in the memory device; and
re-gating circuitry configured to re-gate an output of the gated extend circuitry based at least in part on the start-to-synchronize signal.

2. The memory device of claim 1, wherein the start-to-synchronize signal is based at least in part on the write command.

3. The memory device of claim 1, wherein the start-to-synchronize signal comprises a write start signal indicating that a write operation corresponding to the write command has begun.

4. The memory device of claim 1, wherein the re-gating circuitry comprises a logic gate that receives the output of the gated extend circuitry and a complementary start-to-synchronize signal that is complementary to the start-to-synchronize signal.

5. The memory device of claim 4, wherein the logic gate comprises a NOR gate.

6. The memory device of claim 1, wherein the capture circuitry comprises gated extend re-gate synchronization (GERS) circuitry that comprises the gated extend circuitry and the re-gating circuitry, wherein the gated extend circuitry comprises:
a first NAND gate configured to receive the data strobe and the start-to-synchronize signal as inputs;
first fine-grain pulse extension circuitry configured to extend a pulse on an output of the first NAND gate;
a second NAND gate configured to receive the output of the first NAND gate and an output of the first fine-grain pulse extension circuitry as inputs; and
a first NOR gate configured to receive the data strobe and an output of the second NAND gate as inputs and to output the output of the gated extend circuitry.

7. The memory device of claim 6, wherein the re-gating circuitry comprises a second NOR gate configured to receive the output of the gated extend circuitry and a complementary start-to-synchronize signal as inputs and to output a synchronization signal that is an extension of a state indicative of overlap of the data strobe and the start-to-synchronize signal, wherein the complementary start-to-synchronize signal is complementary to the start-to-synchronize signal.

8. The memory device of claim 7, wherein the capture circuitry comprises complementary GERS circuitry that comprises complementary gated extend circuitry and complementary re-gating circuitry.

9. The memory device of claim 8, wherein the gated extend circuitry comprises:
a third NOR gate configured to receive a complementary data strobe and the complementary start-to-synchronize signal as inputs, wherein the complementary data strobe is complementary to the data strobe;
second fine-grain pulse extension circuitry configured to extend a pulse on an output of the third NOR gate;
a fourth NOR gate configured to receive the output of the third NOR gate and an output of the second fine-grain pulse extension circuitry as inputs; and
a third NAND gate configured to receive the complementary data strobe and an output of the fourth NOR gate as inputs and to output an output of the complementary gated extend circuitry.

10. The memory device of claim 9, wherein the complementary re-gating circuitry comprises a fourth NAND gate configured to receive the output of the complementary gated extend circuitry and the start-to-synchronize signal as inputs and to output a complementary synchronization signal that is complementary to the synchronization signal.

11. The memory device of claim 10, wherein the capture circuitry comprises:
additional GERS circuitry configured to receive the synchronization signal from the GERS circuitry and to output a complementary synchronization compounded signal; and
additional complementary GERS circuitry configured to receive the complementary synchronization signal from the GERS circuitry and to output a synchronization compounded signal that is complementary to the complementary synchronization compounded signal.

12. The memory device of claim 11, wherein the capture circuitry comprises:
a first latch configured to be set using the synchronization compounding signal and to be reset using first reset circuitry that includes first reset gated extend circuitry and first reset re-gating circuitry; and
a second latch configured to be set using the complementary synchronization compounded signal and to be reset using second reset circuitry that includes second reset gated extend circuitry and second reset re-gating circuitry.

13. The memory device of claim 12, wherein the capture circuitry comprises:
a first gate configured to receive an output of the first latch and the complementary data strobe as inputs and to output the internal data strobe; and
a second gate configured to receive an output of the second latch and the data strobe as inputs and to output a complementary internal data strobe that is complementary to the internal data strobe.

14. An electronic device, comprising:
capture circuitry configured to capture a data strobe and generate an internal data strobe, wherein the capture circuitry comprises:
gated-extend re-gate synchronization (GERS) circuitry comprising:
gated extend circuitry configured to extend an overlap of the data strobe with a start-to-synchronize signal that indicates that the data strobe is to be used in the electronic device; and
re-gating circuitry configured to re-gate an output of the gated extend circuitry based at least in part on the start-to-synchronize signal;
additional GERS circuitry comprising:
additional gated extend circuitry configured to receive an output of the GERS circuitry; and
additional re-gating circuitry configured to re-gate an output of the additional gated extend circuitry based at least in part on the output of the GERS circuitry and to output a complementary synchronization signal using strobe negative edge triggering;
complementary gated-extend re-gate synchronization (GERS) circuitry comprising:
complementary gated extend circuitry configured to extend an overlap of a complementary data strobe with a complementary start-to-synchronize signal that indicates that the data strobe is to be used in the electronic device, wherein the complementary data strobe is complementary to the data strobe and the complementary start-to-synchronize signal is complementary to the start-to-synchronize signal; and
complementary re-gating circuitry configured to re-gate an output of the complimentary gated extend circuitry based at least in part on the start-to-synchronize signal; and
additional complementary GERS circuitry comprising:
additional complementary gated extend circuitry configured to receive an output of the complementary GERS circuitry; and
additional complementary re-gating circuitry configured to re-gate an output of the additional complementary gated extend circuitry based at least in part on the output of the complementary GERS circuitry and to output a synchronization signal using strobe negative edge triggering, wherein the synchronization signal is complementary to the complementary synchronization signal.

15. The electronic device of claim 14, wherein the capture circuitry comprises:
first reset circuitry comprising first reset gated extend circuitry and first reset re-gating circuitry that operate based at least in part on the data strobe; and
second reset circuitry comprising second reset gated extend circuitry and second reset re-gating circuitry that operate based at least in part on the complementary data strobe.

16. The electronic device of claim 15, wherein the capture circuitry comprises:
a first latch configured to:
receive the synchronization signal at a set input of the first latch that is configured to set the first latch;
receive an output of the first reset circuitry at a reset input of the first latch that is configured to reset the first latch; and
generate a first output on which the internal data strobe is based; and
a second latch configured to:
receive the complementary synchronization signal at a set input of the second latch that is configured to set the second latch;
receive an output of the second reset circuitry at a reset input of the second latch that is configured to reset the second latch; and
generate a second output on which a complementary internal data strobe is based, wherein the complementary internal data strobe is complementary to the internal data strobe.

17. The electronic device of claim 16, wherein the capture circuitry comprises:
a NOR gate configured to receive the first output and the complementary data strobe as inputs and to output the internal data strobe as an output; and
a NAND gate configured to receive the second output and the data strobe as inputs and to output the complementary internal data strobe as an output.

18. A memory device, comprising:
a command interface configured to receive a write command from a host device;
an input/output interface configured to receive a data strobe;
capture circuitry configured to capture the data strobe and generate an internal data strobe, wherein the capture circuitry comprises:
gated extend re-gate synchronization (GERS) circuitry, comprising:
gated extend circuitry configured to extend an overlap of the data strobe with a start-to-synchronize signal that indicates that the data strobe is to be used in the memory device; and
re-gating circuitry configured to re-gate an output of the gated extend circuitry based at least in part on a complementary start-to-synchronize signal and to generate synchronization signal, wherein the complementary start-to-synchronize signal is complementary to the start-to-synchronize signal;
a latch that is configured to be set using the synchronization signal and to generate an output on which a first internal data strobe is based; and
reset circuitry configured to reset the latch.

19. The memory device of claim 18, wherein the capture circuitry comprises:
complementary GERS circuitry, comprising:
complementary gated extend circuitry configured to extend an overlap of a complementary data strobe with a complementary start-to-synchronize signal, wherein the complementary data strobe is complementary to the data strobe; and
complementary re-gating circuitry configured to re-gate an output of the complementary gated extend circuitry based at least in part on the start-to-synchronize signal and to generate a complementary synchronization signal that is complementary to the synchronization signal;
an additional latch that is configured to be set using the complementary synchronization signal and to generate an output on which a second internal data strobe is based, wherein the second internal data strobe is an internal data strobe true, and the first internal data strobe is an internal data strobe false; and
additional reset circuitry configured to reset the additional latch.

20. The memory device of claim 18, wherein the gated extend circuitry comprises:
a first NAND gate configured to receive the data strobe and the start-to-synchronize signal as inputs;
first fine-grain pulse extension circuitry configured to extend a pulse on an output of the first NAND gate;
a second NAND gate configured to receive the output of the first NAND gate and an output of the first fine-grain pulse extension circuitry as inputs; and
a first NOR gate configured to receive the data strobe and an output of the second NAND gate as inputs and to output the output of the gated extend circuitry.
